(19) United States
(12) Patent Application Publication
(10) Pub. No.: US 2024/0188212 A1
(43) Pub. Date: Jun. 6, 2024

(54) PACKAGE SUBSTRATE ARCHITECTURES WITH IMPROVED COOLING

(71) Applicant: Intel Corporation, Santa Clara, CA (US)

(72) Inventors: Mohammad Mamunur Rahman, Gilbert, AZ (US); Brandon Christian Marin, Gilbert, AZ (US); Gang Duan, Chandler, AZ (US); Srinivas V. Pietambaram, Chandler, AZ (US); Suddhasattwa Nad, Chandler, AZ (US); Rahul Manepalli, Chandler, AZ (US)

(73) Assignee: Intel Corporation, Santa Clara, CA (US)

(21) Appl. No.: 18/061,109

(22) Filed: Dec. 2, 2022

(51) Int. Cl. H05K 1/02; H01L 23/00; H01L 23/427; H01L 23/498; H05K 1/11; H05K 3/46

(52) U.S. Cl. CPC H05K 1/0272; H01L 23/427; H01L 23/49816; H01L 23/49822; H01L 24/16; H01L 24/32; H01L 24/73; H05K 1/0201; H05K 1/112; H05K 3/4644; H05K 3/4697; H01L 2224/16225; H01L 2224/32225; H01L 2224/73253; H05K 2201/064

(57) ABSTRACT

In one embodiment, an integrated circuit package substrate includes a core layer and a plurality of build-up layers on the core layer, each build-up layer comprising a dielectric and metal. The package substrate also includes a cavity, wherein a first portion of the cavity is defined in a first build-up layer, a second portion of the cavity is defined in a second build-up layer, and a third portion of the cavity connects the first portion with the second portion through at least one layer other than first build-up layer and the second build-up layer.

### BACKGROUND

As integrated circuit packages continue to shrink in size and become more complex, removing heat is becoming more of a challenge. Such devices may require or at least be aided by the inclusion of cooling features to disperse heat generated by the integrated circuit components.

### BRIEF DESCRIPTION OF THE DRAWINGS

FIGS. 1A-1B illustrate cross-sectional views of example integrated circuit package substrates that includes vertical cooling channels in accordance with embodiments herein.

FIGS. 2A-2C illustrate an example process for manufacturing an integrated circuit package substrate that includes vertical cooling channels in accordance with embodiments herein.

FIG. 3 illustrates another example process for manufacturing an integrated circuit package substrate that includes vertical cooling channels in accordance with embodiments herein.

FIGS. 4A-4B illustrate yet another example process for manufacturing an integrated circuit package substrate that includes vertical cooling channels in accordance with embodiments herein.

FIG. 5 illustrates an example package substrate that may incorporate or be manufactured using one or more aspects of the present disclosure.

FIG. 6 illustrates an example multi-die package that may incorporate or be manufactured using one or more aspects of the present disclosure.

FIGS. 7A-7B illustrate example systems that may incorporate the glass core architectures described herein.

FIG. 8 is a top view of a wafer and dies that may be included in a microelectronic assembly, in accordance with any of the embodiments disclosed herein.

FIG. 9 is a cross-sectional side view of an integrated circuit device that may be included in a microelectronic assembly, in accordance with any of the embodiments disclosed herein.

FIG. 10 is a block diagram of an example electrical device that may include a microelectronic assembly, in accordance with any of the embodiments disclosed herein.

### DETAILED DESCRIPTION

As integrated circuit packages become more complex (e.g., through the inclusion of active embedded die, glass-based permanent cores, etc.), removing heat from the package is becoming more of a challenge. Microchannels, heat pipes, and immersion cooling techniques have been proposed to address cooling in package substrates, but a complex package can have multiple layers and this can cause some of the layers to exhibit higher temperatures than the rest. And in many instances, the highest temperature within the device may be the (or at least a major) limiting factor in the device's performance.

Accordingly, embodiments herein provide for vertical channels within a package substrate that are formed between different layers of the substrate. Some embodiments may include microchannels and/or heat pipes within different respective layers of a package substrate that are interconnected by vertical channels. The vertical channels may accordingly act to redistribute heat quickly and efficiently between the different layers of the substrate. The interconnection of the cooling architectures may help to alleviate potential localized hotspots within the substrate/device, which can lead to improved overall device performance, through cooling of an attached or embedded circuit die (e.g., an Intel® embedded multi-die interconnect bridge (EMIB)).

Further, some integrated circuit devices may implement a glass-based core layer to provide better substrate rigidity, or for other reasons. However, glass has an inherently low thermal conductivity. Thus, certain embodiments may implement the vertical channels within a glass-based substrate core layer to aid in cooling the glass core layer. In certain embodiments, the vertical channels can be numerous and could function as main microchannels to cool the device, while in other embodiments, there may be only a few vertical channels that connect various cooling architectures (e.g., microchannels, heat pipes, immersion cooling layers, etc.) and thus prevent hot spot formation.

In certain embodiments, the cooling microchannels and/or heat pipes within a package substrate (including both those within a single layer and those that traverse multiple layers of the substrate such as the vertical channels described herein) may be coated with a hydrophilic material layer that further aids in cooling of the substrate/device. For example, where a microchannel for cooling is implemented within, between, or on a glass-based layer (e.g., a glass core) of a substrate, the cooling performance may be degraded when the temperature of the glass reaches the Leidenfrost temperature and forms an insulating vapor layer between the glass and the cooling fluid. The inclusion of a hydrophilic material layer on a surface of the glass may accordingly prevent or delay the formation of the vapor layer and enhance the cooling performance of the cooling architecture. The hydrophilic material may also be used in non-glass embodiments as well to aid in cooling.

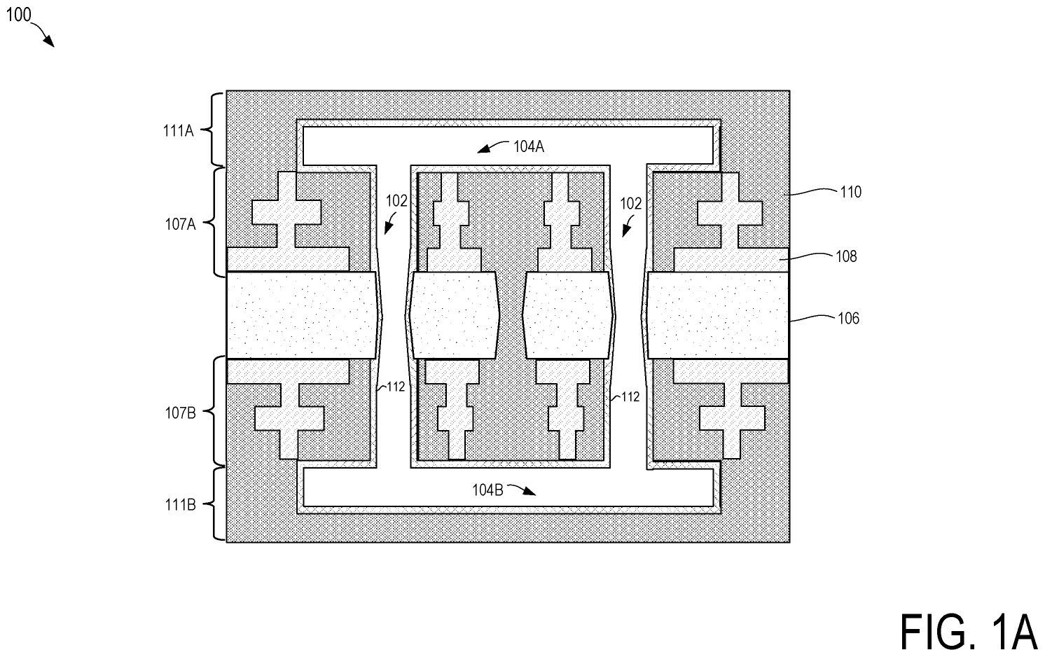

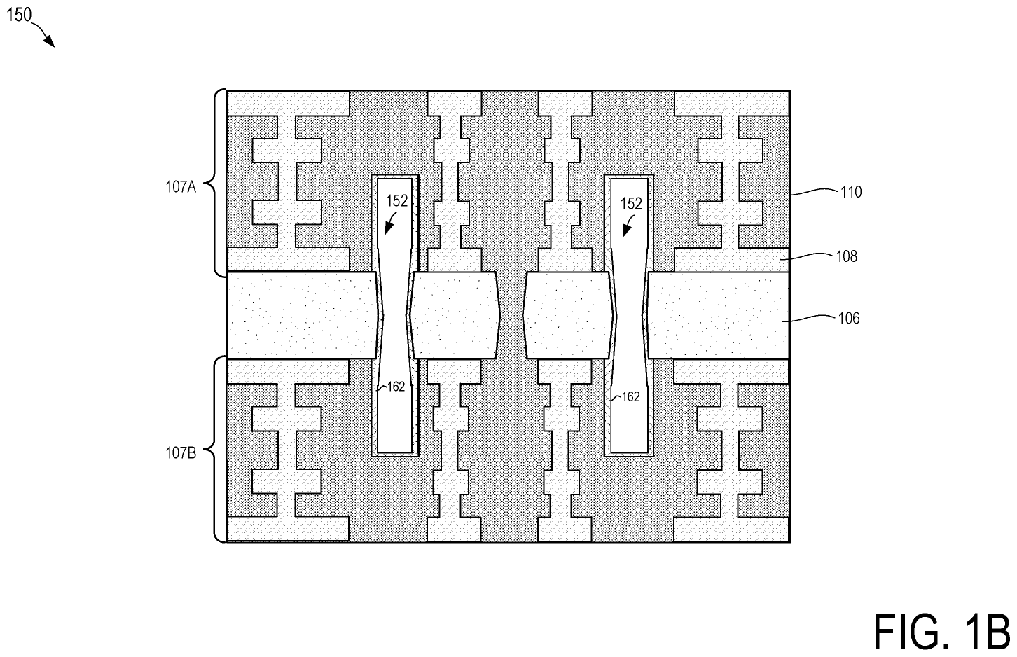

FIGS. 1A-1B illustrate cross-sectional views of example integrated circuit package substrates 100, 150 that includes vertical cooling channels 102, 152 in accordance with embodiments herein. The package substrates 100, 150 each include a core layer 106, which may be made from traditional organic materials or from a type of glass (e.g., silica, a borosilicate material, or spin-on-glass (SOG)). Each side of the core layer 106 has build-up layers 107 formed thereon, with the build-up layers 107 having a number of metallization layers that include dielectric layers (e.g., 108) and metal traces or vias (e.g., 110).

Referring to FIG. 1A, the example package substrate 100 also includes microchannels 104A, 104B formed within their own layers 111A, 111B, respectively, on the build-up layers 107A, 107B, respectively. The microchannels 104 may be cavities formed within the substrate 100 that run into/out of the page, and may function to spread heat within the substrate (e.g., to prevent localized hotspots). For instance, the microchannels 104 may include hollow heat conducting materials through which a fluid (e.g., liquid) flows (into/out of the page) to spread the heat. The microchannels 104 may be of any geometrical form. For example, the microchannels 104 may be rectangular, triangular, trapezoidal, circular, or oval in their cross-sections. The microchannels 104, in some embodiments, may be an open channel that is sealed with a pump to cause the fluid to flow through the microchannel. In other embodiments, the microchannels 104 may be sealed in the integration process to result in a closed heat pipe structure in which fluid (e.g., liquid) flows through expansion and compression in response to heating and cooling, respectively. In a heat pipe, the liquid can diffuse through the microchannel based on capillary action.

As shown, the cavities of the microchannels 104 are joined together via the channels 102 within the substrate 100. In some embodiments, the vertical channels 102 may be ducts that connect the microchannels 104 together (e.g., connecting certain portions of the microchannels together), and may be part of a series of vertical ducts that connect the microchannels 104 together. In other embodiments, the vertical channels 102 run into/out of the page along with the microchannels 104 to create a larger overall microchannel in the substrate 100.

In the example shown, the microchannels 104 and vertical channels 102 together form an overall cavity within the substrate 100 in which a fluid may flow as described above. The microchannel 104A may be considered as a first portion of the overall cavity that is defined by a first (generally rectangular) cross-section in a first build-up layer of the substrate 100, the microchannel 104B may be considered as a second portion of the overall cavity and is defined by a second (also generally rectangular) cross-section in a second build-up layer of the substrate, and the vertical channels 102 may be considered as third and fourth portions of the overall cavity and are defined by a third cross-section between the first build-up layer and the second build-up layer in which the microchannels are defined.

Furthermore, in the example shown, the sidewalls of the channels 102 include a hydrophilic material layer 112, which may prevent a vapor layer from forming at the interface between the core layer 106 and the channel 102 at the Leidenfrost temperature, which may be beneficial for cooling as described above. In addition, the walls of the microchannels 104 may include hydrophilic material layer as well (as shown in FIGS. 1A and 1B). However, certain embodiments may not include a hydrophilic material layer in one or both of the channels 102 or microchannels 104.

Referring now to FIG. 1B, the example package substrate 150 includes vertical cavities 152 that form microchannels running into/out of the page in which a fluid may flow. The vertical microchannels may function in the same manner as the microchannels 104, e.g., to spread heat within the substrate. The vertical microchannels formed by the cavities 152 may include hollow heat conducting materials through which a fluid (e.g., liquid) flows (into/out of the page) to spread the heat. In the example shown, the cavities 152 include a hydrophilic material layer 162 that is similar to the layer 112 in FIG. 1A.

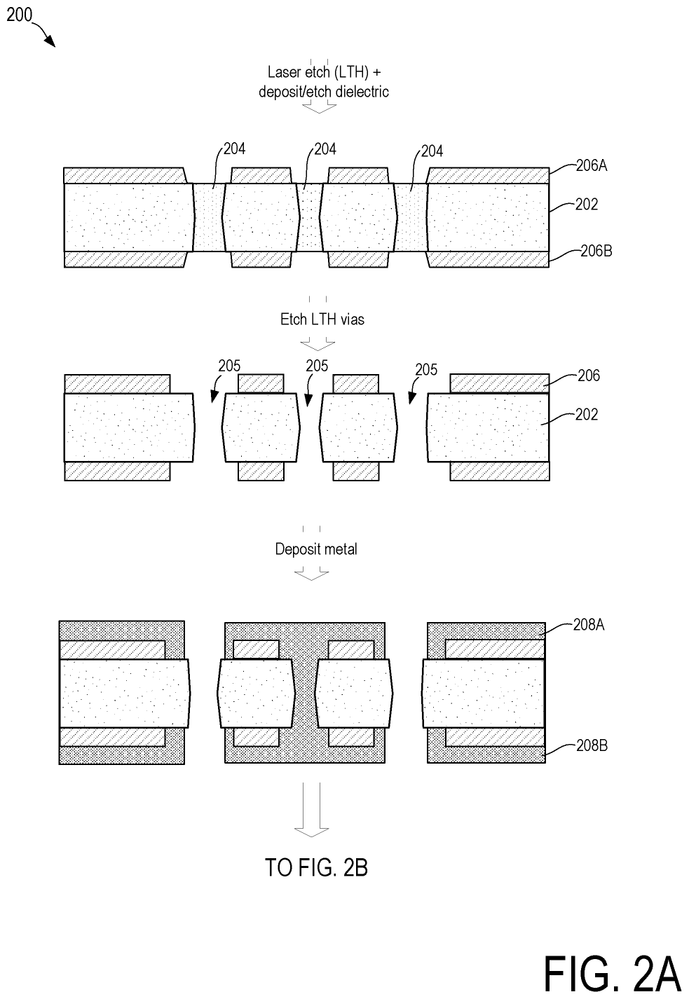

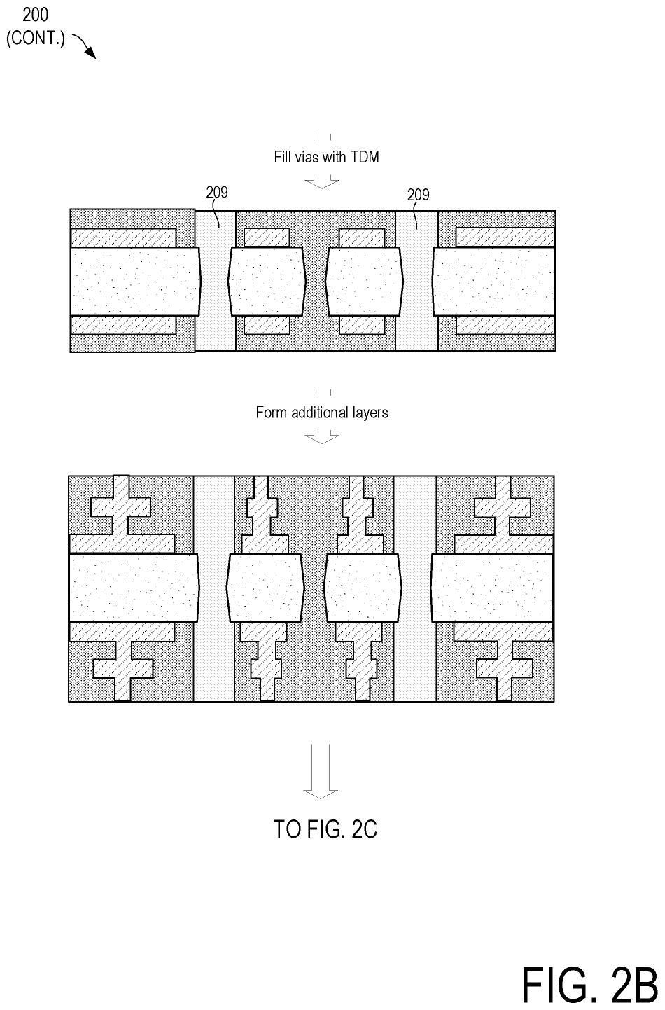

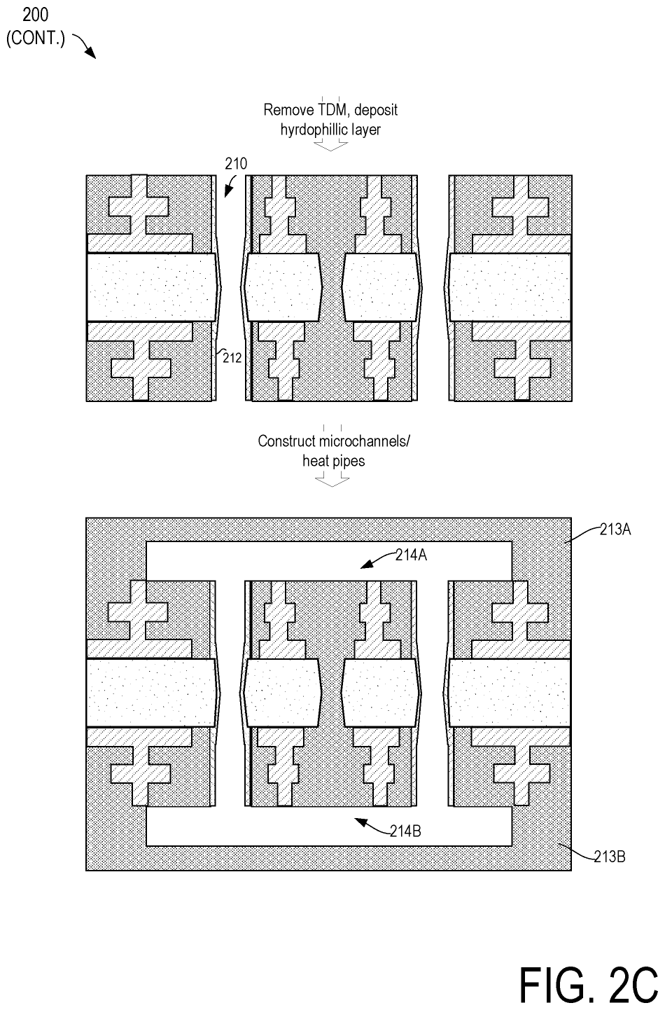

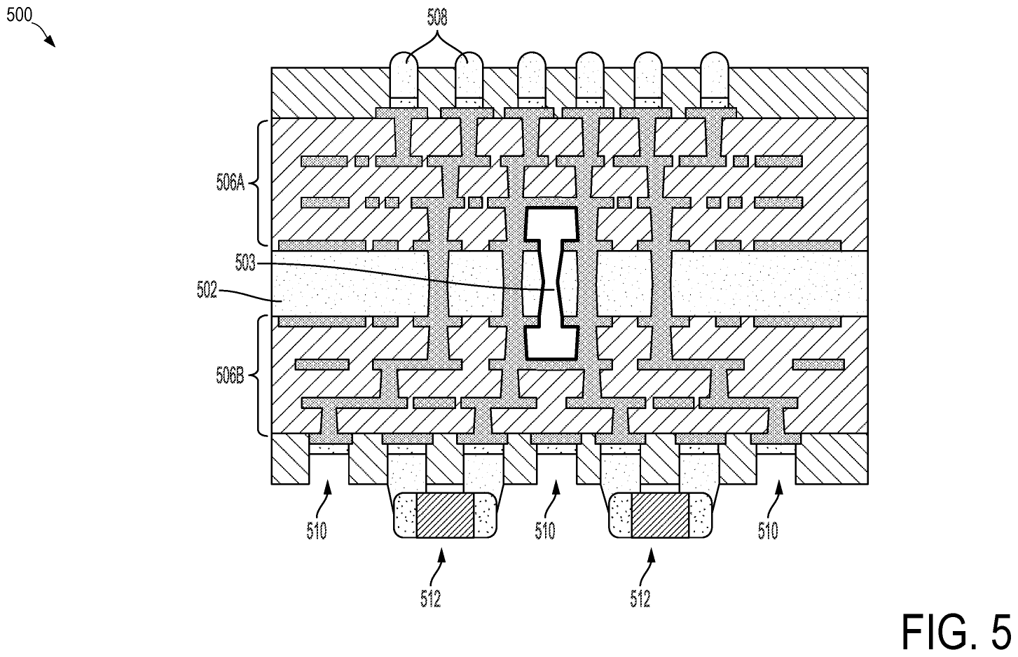

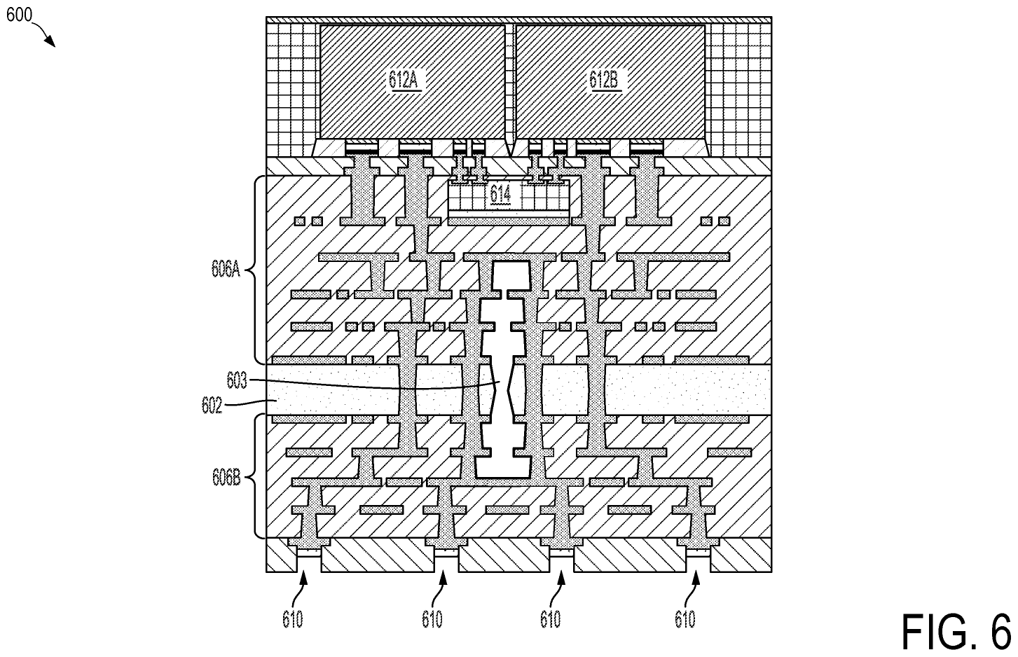

FIGS. 2A-2C illustrate an example process 200 for manufacturing an integrated circuit package substrate that includes vertical cooling channels in accordance with embodiments herein. The example process shown may include additional, fewer, or different operations than those shown or described below. In some embodiments, one or more of the operations shown in FIGS. 2A-2C include multiple operations, sub-operations, etc. The illustrations of FIGS. 2A-2C may thus represent different stages in the manufacturing process. Aspects of the process 200 may be used to manufacture a package substrate such as those shown in FIGS. 5 and 6, or other embodiments described herein.

The example process 200 begins by performing a laser etch portions 204 of a glass core layer 202 in what will become vias through the core layer 202. The glass core layer 202 may be formed from any suitable type of glass material, such as silica, a borosilicate material, or a spin-on-glass (SOG) material. Dielectric layers 206A, 206B are then formed and patterned on either side of the glass core layer 202. The portions 204 are then etched away to form the vias 205 through the core layer 202, and metal is deposited on each side of the stack as shown in the bottom illustration of FIG. 2A. The vias 205 are then filled with a thermally decomposable material (TDM) 209. This sort of process is repeated to form additional layers comprising dielectric, metal, and/or TDM (e.g., as shown in the bottom illustration of FIG. 2B). Then, the TDM material is removed and a hydrophilic layer 212 is deposited on the sidewalls of the cavities 210 that are left after the TDM material is removed. Finally, cavities/microchannels 214A, 214B are formed on each side of the stack as shown by depositing/patterning one or more layers of metal (e.g., 213A, 213B) to form the cavities. In some embodiments, a hydrophilic material (the same or similar to the material used for the layer 212) may also be deposited on the walls of the cavities 214.

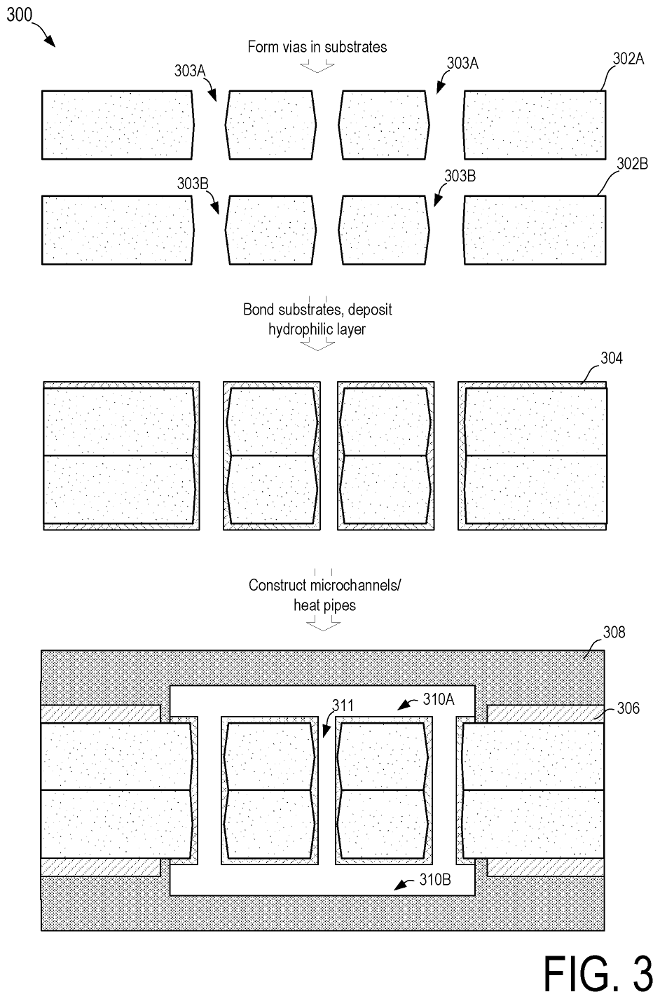

FIG. 3 illustrates another example process 300 for manufacturing an integrated circuit package substrate that includes vertical cooling channels in accordance with embodiments herein. The example process shown may include additional, fewer, or different operations than those shown or described below. In some embodiments, one or more of the operations shown in FIG. 3 include multiple operations, sub-operations, etc. The illustrations of FIG. 3 may thus represent different stages in the manufacturing process. Aspects of the process 300 may be used to manufacture a package substrate such as those shown in FIGS. 5 and 6, or other embodiments described herein.

The example process 300 begins by forming vias 303 in two or more substrates 302, and then bonding the substrates 302 together such that the vias 303 are aligned with one another. The substrates 302 may be formed from any suitable material, such as an organic, inorganic, or glass material (e.g., silica, a borosilicate material, or SOG material), and the vias may be formed in any suitable manner (e.g., a laser through hole (LTH) process for glass substrates). In some instances, the bonded substrates may form a first layer of a package substrate (e.g., a core layer), and the substrate 302A may be considered a first sub-layer of the first package substrate layer and the substrate 302B may be considered as a second sub-layer of the first package substrate layer.

A hydrophilic layer 304 can then be deposited on the exposed surfaces of the bonded substrates, including the vias 303, and cavities/microchannels 310 are formed on each side of the bonded substrates. The cavities/microchannels 310 may be formed by patterning layers of dielectric (e.g., 306) and metal (e.g., 308) in a manner similar to that shown in FIG. 2. In some embodiments, a hydrophilic material (the same or similar to the material used for the layer 304) may also be deposited on the walls of the cavities 310.

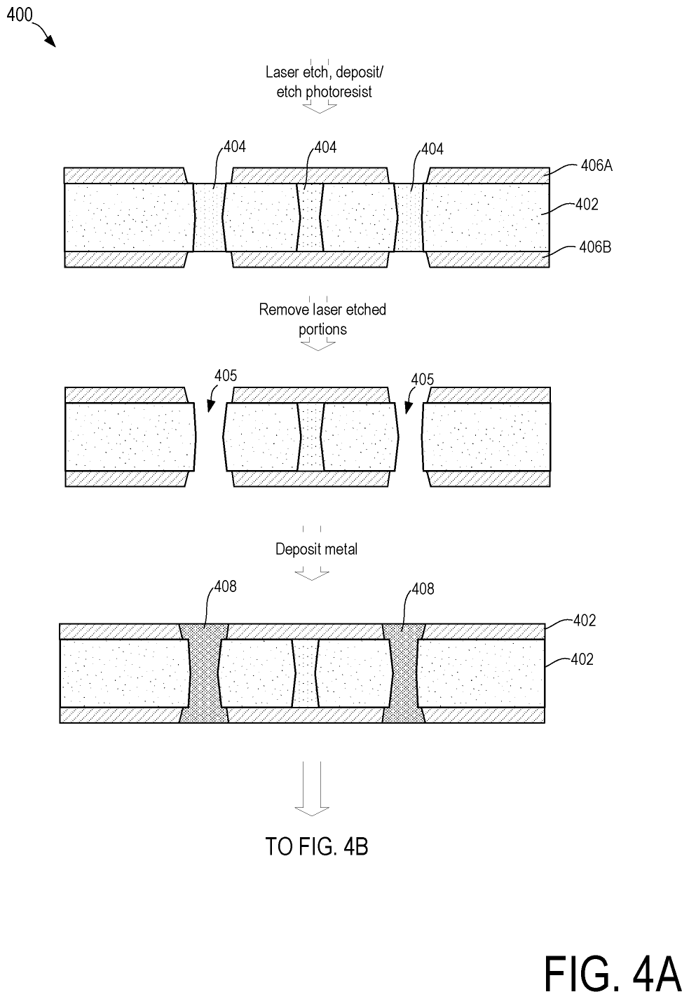

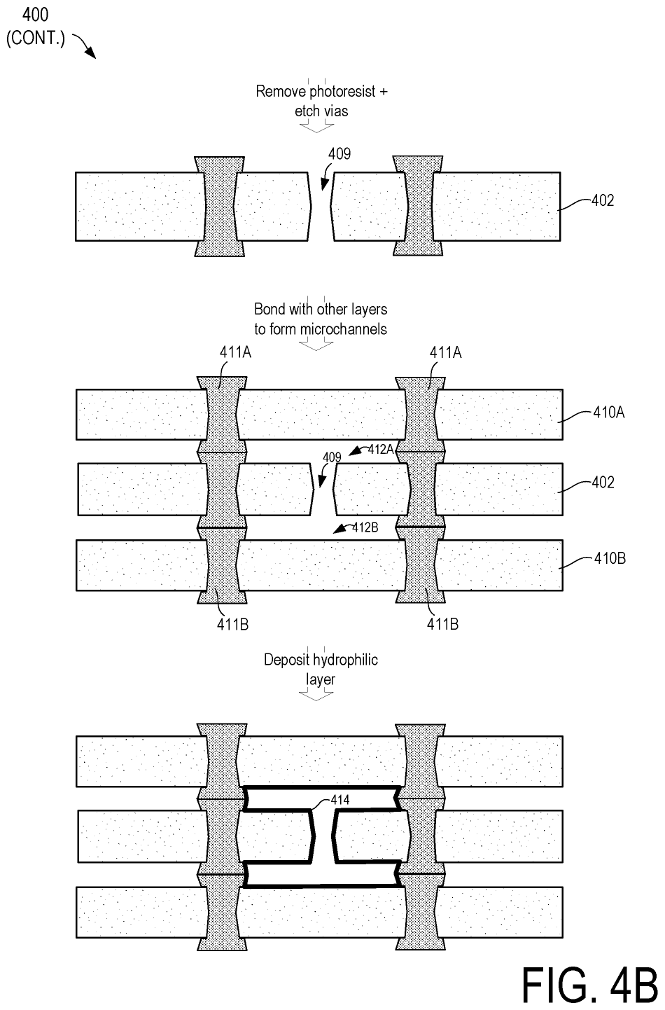

FIGS. 4A-4B illustrate yet another example process 400 for manufacturing an integrated circuit package substrate that includes vertical cooling channels in accordance with embodiments herein. The example process shown may include additional, fewer, or different operations than those shown or described below. In some embodiments, one or more of the operations shown in FIGS. 4A-4B include multiple operations, sub-operations, etc. The illustrations of FIGS. 4A-4B may thus represent different stages in the manufacturing process. Aspects of the process 400 may be used to manufacture a package substrate such as those shown in FIGS. 5 and 6, or other embodiments described herein.

The example process 400 begins by performing a laser etch portions 404 of a glass core layer 402 in what will become vias through the core layer 402. The glass core layer 402 may be formed from any suitable type of glass material, such as silica, a borosilicate material, or a spin-on-glass (SOG) material. Dielectric layers 406A, 406B are then formed and patterned on either side of the glass core layer 402. The portions 404 are then etched away to form the vias 405 through the core layer 402, and metal 408 is deposited to fill the vias 405. The photoresist layers 406 are then removed, and the remaining laser etched portion 404 of the core layer 402 is etched away to form another via 409 in the core layer 402.

The core layer 402 is then bonded to other substrate layers 410, with a first core layer 410A being bonded to a top side of the core layer 402 and a second core layer 410B being bonded to a bottom side of the core layer 402. Each core layer 410 includes metal vias 411 (which may be formed in a similar manner as the metal vias 408). To bond the layers, the metal vias 411 may be metal-to-metal bonded with the metal vias 408, which functions to form cavities/microchannels 412 on each side of the core layer 402 that are connected together by the via 409 through the core layer 402. A hydrophilic material 414 can then be deposited on the walls of the via 409 and microchannels 412 as shown.

In any of the above processes, the cavities may be filled with a fluid, such as a liquid, that is used for aiding cooling within the package substrate prior to sealing of the cavities. For example, the cavities formed may define one or more sealed heat pipe structures in which the fluid diffuses through the microchannel, e.g., by capillary action.

FIG. 5 illustrates an example package substrate 500 that may incorporate or be manufactured using one or more aspects of the present disclosure. The example package substrate 500 includes a core 502 with build-up layers 506 on each side. The core 502 may be made of an organic, inorganic, or glass-based material. The package substrate 500 also includes a cavity 503 formed therein, which includes microchannels on either side of the core 502 connected together by a via through the core 502. The cavity 503 may be formed using one or more of the techniques described herein. The package substrate 500 may, in certain embodiments, also include other cavities similar to the cavity 503, with microchannels in layers on either side of the core 502 (similar to the cavity 503), or with microchannels in layers that are on the same side of the core 502 (e.g., contained completely within one of the build-up layers 506A, 506B.

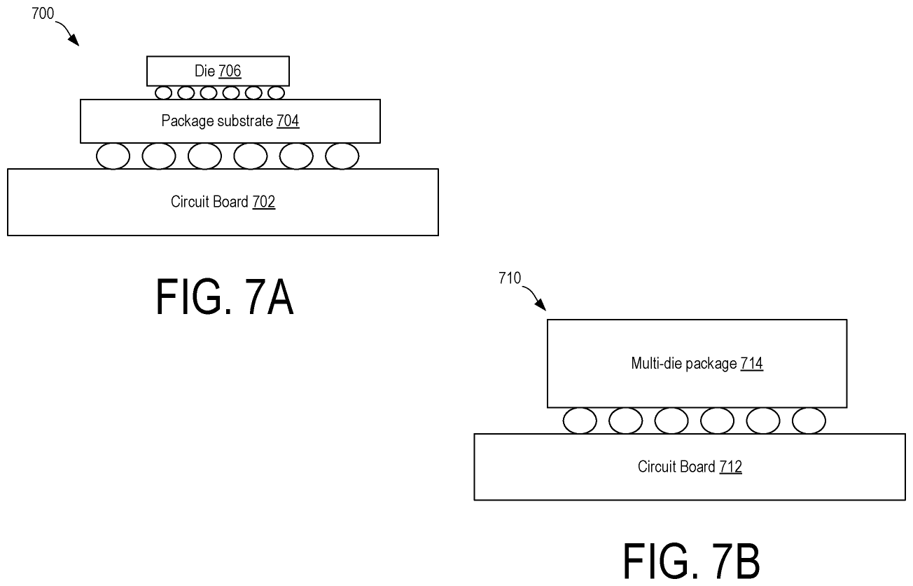

The build-up layers 506 are formed on the top and bottom sides of the core 502, with build-up layers 506A on the top side of the glass core 502 and the build-up layers 506B on bottom side of the core 502. The layers 506 may be made from a traditional dielectric material in certain embodiments, or from a glass-based material such as SOG. The layers 506 include metal pillars, vias, and/or traces as shown to electrically couple the solder bumps 508 at the top of the package substrate 500 with the pads 510 at the bottom of the substrate. In certain instances, for example, an integrated circuit die may be coupled to a top side of the package substrate 500 and connect to the solder bumps 508, and the package substrate 500 may be coupled to a circuit board (e.g., a motherboard, main board, etc.) via the pads 510 at the bottom of the package substrate 500. For instance, the package substrate 500 may be incorporated into the system 700 of FIG. 7A as the package substrate 704. The package substrate 500 also includes land side capacitors 512 coupled on a bottom side of the package substrate 500.

FIG. 6 illustrates an example multi-die package 600 that may incorporate or be manufactured using one or more aspects of the present disclosure. The multi-die package 600 includes build-up layers 606 formed on the top and bottom sides of the core 602, with build-up layers 606A formed on the top side of the core 602 and the build-up layers 606B formed on bottom side of the core 602. The build-up layers 606 may be formed from traditional dielectric materials. The layers 606 include metal pillars, vias, and/or traces as shown to electrically couple the integrated circuit (IC) dies 612 at the top of the multi-die package 600 with the pads 610 at the bottom of the package 600. As with the substrate 500, the package 600 a cavity 603 formed therein, which includes microchannels on either side of the core 602 connected together by a via through the core 602. The cavity 603 may be formed using one or more of the techniques described herein. The package substrate 500 may, in certain embodiments, also include other cavities similar to the cavity 603, with microchannels in layers on either side of the core 602 (similar to the cavity 603), or with microchannels in layers that are on the same side of the core 602 (e.g., contained completely within one of the build-up layers 606A, 606B.

In addition, there is a bridge component 614 located in the build-up layers 606A that electrically couples the first IC die 612A with the second IC die 612B. The bridge component 614 may include passive and/or active components to interconnect the IC dies 612. The bridge component 614 may be an Intel® embedded multi-die interconnect bridge (EMIB) in certain embodiments. In certain instances, the multi-die package 600 may be coupled to a circuit board (e.g., a motherboard, main board, etc.) via the pads 610 at the bottom of the package 600. For instance, the package 600 may be incorporated into the system 710 of FIG. 7B as the multi-die package 714.

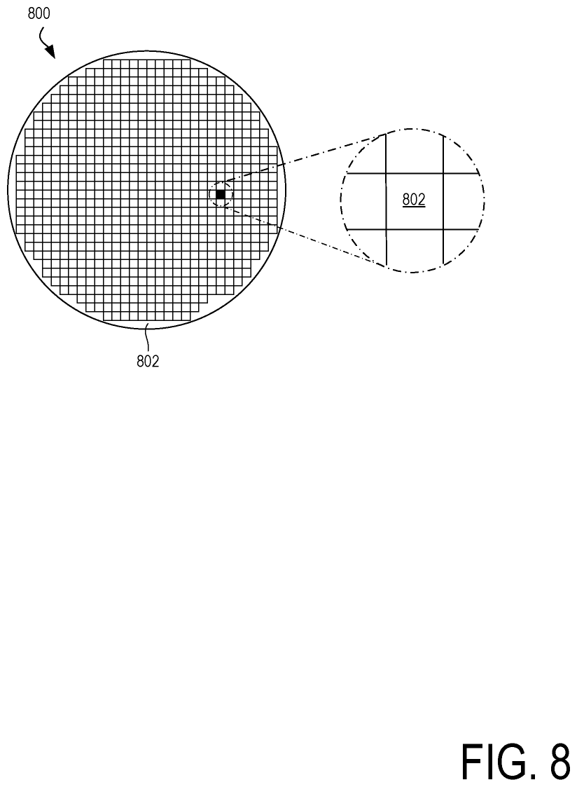

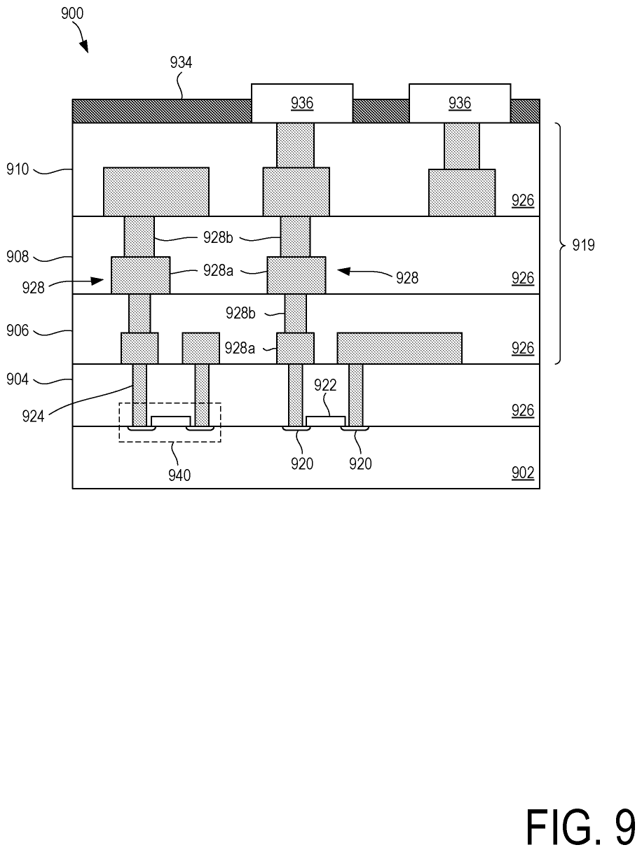

FIGS. 7A-7B illustrate example systems 700, 710 that may incorporate the SOG-based architectures described herein. The example system 700 of FIG. 7A includes a circuit board 702, which may be implemented as a motherboard or main board of a computer system in some embodiments. The example system 700 also includes a package substrate 704 with an integrated circuit die 806 attached to the package substrate 704. The die 706 may be a packaged or unpacked integrated circuit product that includes one or more integrated circuit dies (e.g., the die 802 of FIG. 8, the integrated circuit device 900 of FIG. 9) and/or one or more other suitable components. The die 706 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the die 706 can comprise one or more additional active or passive devices such as capacitors, decoupling capacitors, resistors, inductors, fuses, diodes, transformers, sensors, electrostatic discharge (ESD) devices, and memory devices. In addition to comprising one or more processor units, the die 706 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. The package substrate 704 may provide electrical connections between the die 706 and the circuit board 702.

Similar to the system 700, the system 710 also includes a circuit board 712, which may be implemented as a motherboard or main board of a computer system in some embodiments. The system 710 also includes a multi-die package 714, which includes multiple integrated circuits/dies (e.g., 706), and interconnections between the dies in one or more metallization layers. The multi-die package 714 may include, for example, one or more silicon interposers, one or more silicon bridges embedded in the package substrate (e.g., an Intel® embedded multi-die interconnect bridge (EMIB)), or combinations thereof.

The main circuit boards 710, 712 may provide electrical connections to other components of a computer system, e.g., memory, storage, network interfaces, peripheral devices, power supplies, etc. The main circuit board may include one or more traces and circuit components to provide interconnects between such computer system components.

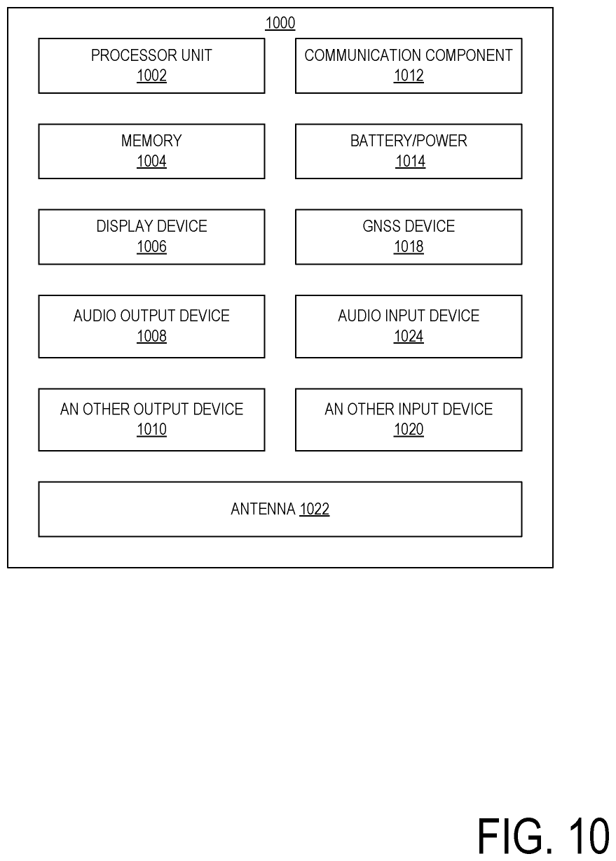

FIG. 8 is a top view of a wafer 800 and dies 802 that may be implemented in or along with any of the embodiments disclosed herein. The wafer 800 may be composed of semiconductor material and may include one or more dies 802 having integrated circuit structures formed on a surface of the wafer 800. The individual dies 802 may be a repeating unit of an integrated circuit product that includes any suitable integrated circuit. After the fabrication of the semiconductor product is complete, the wafer 800 may undergo a singulation process in which the dies 802 are separated from one another to provide discrete “chips” of the integrated circuit product. The die 802 may include one or more transistors (e.g., some of the transistors 940 of FIG. 9, discussed below), supporting circuitry to route electrical signals to the transistors, passive components (e.g., signal traces, resistors, capacitors, or inductors), and/or any other integrated circuit components. In some embodiments, the wafer 800 or the die 802 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 802. For example, a memory array formed by multiple memory devices may be formed on a same die 802 as a processor unit (e.g., the processor unit 1002 of FIG. 10) or other logic that is configured to store information in the memory devices or execute instructions stored in the memory array.

FIG. 9 is a cross-sectional side view of an integrated circuit device 900 that may be included in any of the embodiments disclosed herein. One or more of the integrated circuit devices 900 may be included in one or more dies 802 (FIG. 8). The integrated circuit device 900 may be formed on a die substrate 902 (e.g., the wafer 800 of FIG. 8) and may be included in a die (e.g., the die 802 of FIG. 8). The die substrate 902 may be a semiconductor substrate composed of semiconductor material systems including, for example, n-type or p-type materials systems (or a combination of both). The die substrate 902 may include, for example, a crystalline substrate formed using a bulk silicon or a silicon-on-insulator (SOI) substructure. In some embodiments, the die substrate 902 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 902. Although a few examples of materials from which the die substrate 902 may be formed are described here, any material that may serve as a foundation for an integrated circuit device 900 may be used. The die substrate 902 may be part of a singulated die (e.g., the dies 802 of FIG. 8) or a wafer (e.g., the wafer 800 of FIG. 8).

The integrated circuit device 900 may include one or more device layers 904 disposed on the die substrate 902. The device layer 904 may include features of one or more transistors 940 (e.g., metal oxide semiconductor field-effect transistors (MOSFETs)) formed on the die substrate 902. The transistors 940 may include, for example, one or more source and/or drain (S/D) regions 920, a gate 922 to control current flow between the S/D regions 920, and one or more S/D contacts 924 to route electrical signals to/from the S/D regions 920. The transistors 940 may include additional features not depicted for the sake of clarity, such as device isolation regions, gate contacts, and the like. The transistors 940 are not limited to the type and configuration depicted in FIG. 9 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 9, a transistor 940 may include a gate 922 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 940 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 940 along the source-channel-drain direction, the gate electrode may consist of a U-shaped structure that includes a bottom portion substantially parallel to the surface of the die substrate 902 and two sidewall portions that are substantially perpendicular to the top surface of the die substrate 902. In other embodiments, at least one of the metal layers that form the gate electrode may simply be a planar layer that is substantially parallel to the top surface of the die substrate 902 and does not include sidewall portions substantially perpendicular to the top surface of the die substrate 902. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 920 may be formed within the die substrate 902 adjacent to the gate 922 of individual transistors 940. The S/D regions 920 may be formed using an implantation/diffusion process or an etching/deposition process, for example. In the former process, dopants such as boron, aluminum, antimony, phosphorous, or arsenic may be ion-implanted into the die substrate 902 to form the S/D regions 920. An annealing process that activates the dopants and causes them to diffuse farther into the die substrate 902 may follow the ion-implantation process. In the latter process, the die substrate 902 may first be etched to form recesses at the locations of the S/D regions 920. An epitaxial deposition process may then be carried out to fill the recesses with material that is used to fabricate the S/D regions 920. In some implementations, the S/D regions 920 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 920 may be formed using one or more alternate semiconductor materials such as germanium or a group III-V material or alloy. In further embodiments, one or more layers of metal and/or metal alloys may be used to form the S/D regions 920.

Electrical signals, such as power and/or input/output (I/O) signals, may be routed to and/or from the devices (e.g., transistors 940) of the device layer 904 through one or more interconnect layers disposed on the device layer 904 (illustrated in FIG. 9 as interconnect layers 906-910). For example, electrically conductive features of the device layer 904 (e.g., the gate 922 and the S/D contacts 924) may be electrically coupled with the interconnect structures 928 of the interconnect layers 906-910. The one or more interconnect layers 906-910 may form a metallization stack (also referred to as an “ILD stack”) 919 of the integrated circuit device 900.

The interconnect structures 928 may be arranged within the interconnect layers 906-910 to route electrical signals according to a wide variety of designs; in particular, the arrangement is not limited to the particular configuration of interconnect structures 928 depicted in FIG. 9. Although a particular number of interconnect layers 906-910 is depicted in FIG. 9, embodiments of the present disclosure include integrated circuit devices having more or fewer interconnect layers than depicted.

In some embodiments, the interconnect structures 928 may include lines 928a and/or vias 928b filled with an electrically conductive material such as a metal. The lines 928a may be arranged to route electrical signals in a direction of a plane that is substantially parallel with a surface of the die substrate 902 upon which the device layer 904 is formed. For example, the lines 928a may route electrical signals in a direction in and out of the page and/or in a direction across the page from the perspective of FIG. 9. The vias 928b may be arranged to route electrical signals in a direction of a plane that is substantially perpendicular to the surface of the die substrate 902 upon which the device layer 904 is formed. In some embodiments, the vias 928b may electrically couple lines 928a of different interconnect layers 906-910 together.

The interconnect layers 906-910 may include a dielectric material 926 disposed between the interconnect structures 928, as shown in FIG. 9. In some embodiments, dielectric material 926 disposed between the interconnect structures 928 in different ones of the interconnect layers 906-910 may have different compositions; in other embodiments, the composition of the dielectric material 926 between different interconnect layers 906-910 may be the same. The device layer 904 may include a dielectric material 926 disposed between the transistors 940 and a bottom layer of the metallization stack as well. The dielectric material 926 included in the device layer 904 may have a different composition than the dielectric material 926 included in the interconnect layers 906-910; in other embodiments, the composition of the dielectric material 926 in the device layer 904 may be the same as a dielectric material 926 included in any one of the interconnect layers 906-910.

A first interconnect layer 906 (referred to as Metal 1 or “M1”) may be formed directly on the device layer 904. In some embodiments, the first interconnect layer 906 may include lines 928a and/or vias 928b, as shown. The lines 928a of the first interconnect layer 906 may be coupled with contacts (e.g., the S/D contacts 924) of the device layer 904. The vias 928b of the first interconnect layer 906 may be coupled with the lines 928a of a second interconnect layer 908.

The second interconnect layer 908 (referred to as Metal 2 or “M2”) may be formed directly on the first interconnect layer 906. In some embodiments, the second interconnect layer 908 may include via 928b to couple the lines 928 of the second interconnect layer 908 with the lines 928a of a third interconnect layer 910. Although the lines 928a and the vias 928b are structurally delineated with a line within individual interconnect layers for the sake of clarity, the lines 928a and the vias 928b may be structurally and/or materially contiguous (e.g., simultaneously filled during a dual-damascene process) in some embodiments.

The third interconnect layer 910 (referred to as Metal 3 or “M3”) (and additional interconnect layers, as desired) may be formed in succession on the second interconnect layer 908 according to similar techniques and configurations described in connection with the second interconnect layer 908 or the first interconnect layer 906. In some embodiments, the interconnect layers that are “higher up” in the metallization stack 919 in the integrated circuit device 900 (i.e., farther away from the device layer 904) may be thicker that the interconnect layers that are lower in the metallization stack 919, with lines 928a and vias 928b in the higher interconnect layers being thicker than those in the lower interconnect layers.

The integrated circuit device 900 may include a solder resist material 934 (e.g., polyimide or similar material) and one or more conductive contacts 936 formed on the interconnect layers 906-910. In FIG. 9, the conductive contacts 936 are illustrated as taking the form of bond pads. The conductive contacts 936 may be electrically coupled with the interconnect structures 928 and configured to route the electrical signals of the transistor(s) 940 to external devices. For example, solder bonds may be formed on the one or more conductive contacts 936 to mechanically and/or electrically couple an integrated circuit die including the integrated circuit device 900 with another component (e.g., a printed circuit board or a package substrate). The integrated circuit device 900 may include additional or alternate structures to route the electrical signals from the interconnect layers 906-910; for example, the conductive contacts 936 may include other analogous features (e.g., posts) that route the electrical signals to external components.

In some embodiments in which the integrated circuit device 900 is a double-sided die, the integrated circuit device 900 may include another metallization stack (not shown) on the opposite side of the device layer(s) 904. This metallization stack may include multiple interconnect layers as discussed above with reference to the interconnect layers 906-910, to provide conductive pathways (e.g., including conductive lines and vias) between the device layer(s) 904 and additional conductive contacts (not shown) on the opposite side of the integrated circuit device 900 from the conductive contacts 936.

In other embodiments in which the integrated circuit device 900 is a double-sided die, the integrated circuit device 900 may include one or more through silicon vias (TSVs) through the die substrate 902; these TSVs may make contact with the device layer(s) 904, and may provide conductive pathways between the device layer(s) 904 and additional conductive contacts (not shown) on the opposite side of the integrated circuit device 900 from the conductive contacts 936. In some embodiments, TSVs extending through the substrate can be used for routing power and ground signals from conductive contacts on the opposite side of the integrated circuit device 900 from the conductive contacts 936 to the transistors 940 and any other components integrated into the die 900, and the metallization stack 919 can be used to route I/O signals from the conductive contacts 936 to transistors 940 and any other components integrated into the die 900.

Multiple integrated circuit devices 900 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

FIG. 10 is a block diagram of an example electrical device 1000 that may include one or more of the embodiments disclosed herein. For example, any suitable ones of the components of the electrical device 1000 may include one or more of assemblies 100, integrated circuit devices 900, or integrated circuit dies 802 disclosed herein. A number of components are illustrated in FIG. 10 as included in the electrical device 1000, but any one or more of these components may be omitted or duplicated, as suitable for the application. In some embodiments, some or all of the components included in the electrical device 1000 may be attached to one or more motherboards mainboards, or system boards. In some embodiments, one or more of these components are fabricated onto a single system-on-a-chip (SoC) die.

Additionally, in various embodiments, the electrical device 1000 may not include one or more of the components illustrated in FIG. 10, but the electrical device 1000 may include interface circuitry for coupling to the one or more components. For example, the electrical device 1000 may not include a display device 1006, but may include display device interface circuitry (e.g., a connector and driver circuitry) to which a display device 1006 may be coupled. In another set of examples, the electrical device 1000 may not include an audio input device 1024 or an audio output device 1008, but may include audio input or output device interface circuitry (e.g., connectors and supporting circuitry) to which an audio input device 1024 or audio output device 1008 may be coupled.

The electrical device 1000 may include one or more processor units 1002 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1002 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1000 may include a memory 1004, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1004 may include memory that is located on the same integrated circuit die as the processor unit 1002. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1000 can comprise one or more processor units 1002 that are heterogeneous or asymmetric to another processor unit 1002 in the electrical device 1000. There can be a variety of differences between the processing units 1002 in a system in terms of a spectrum of metrics of merit including architectural, microarchitectural, thermal, power consumption characteristics, and the like. These differences can effectively manifest themselves as asymmetry and heterogeneity among the processor units 1002 in the electrical device 1000.

In some embodiments, the electrical device 1000 may include a communication component 1012 (e.g., one or more communication components). For example, the communication component 1012 can manage wireless communications for the transfer of data to and from the electrical device 1000. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1012 may operate in accordance with other wireless protocols in other embodiments. The electrical device 1000 may include an antenna 1022 to facilitate wireless communications and/or to receive other wireless communications (such as AM or FM radio transmissions).

In some embodiments, the communication component 1012 may manage wired communications, such as electrical, optical, or any other suitable communication protocols (e.g., IEEE 802.3 Ethernet standards). As noted above, the communication component 1012 may include multiple communication components. For instance, a first communication component 1012 may be dedicated to shorter-range wireless communications such as Wi-Fi or Bluetooth, and a second communication component 1012 may be dedicated to longer-range wireless communications such as global positioning system (GPS), EDGE, GPRS, CDMA, WiMAX, LTE, EV-DO, or others. In some embodiments, a first communication component 1012 may be dedicated to wireless communications, and a second communication component 1012 may be dedicated to wired communications.

The electrical device 1000 may include battery/power circuitry 1014. The battery/power circuitry 1014 may include one or more energy storage devices (e.g., batteries or capacitors) and/or circuitry for coupling components of the electrical device 1000 to an energy source separate from the electrical device 1000 (e.g., AC line power).

The electrical device 1000 may include a display device 1006 (or corresponding interface circuitry, as discussed above). The display device 1006 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1000 may include an audio output device 1008 (or corresponding interface circuitry, as discussed above). The audio output device 1008 may include any embedded or wired or wirelessly connected external device that generates an audible indicator, such speakers, headsets, or earbuds.

The electrical device 1000 may include an audio input device 1024 (or corresponding interface circuitry, as discussed above). The audio input device 1024 may include any embedded or wired or wirelessly connected device that generates a signal representative of a sound, such as microphones, microphone arrays, or digital instruments (e.g., instruments having a musical instrument digital interface (MIDI) output). The electrical device 1000 may include a Global Navigation Satellite System (GNSS) device 1018 (or corresponding interface circuitry, as discussed above), such as a Global Positioning System (GPS) device. The GNSS device 1018 may be in communication with a satellite-based system and may determine a geolocation of the electrical device 1000 based on information received from one or more GNSS satellites, as known in the art.

The electrical device 1000 may include another output device 1010 (or corresponding interface circuitry, as discussed above). Examples of the other output device 1010 may include an audio codec, a video codec, a printer, a wired or wireless transmitter for providing information to other devices, or an additional storage device.

The electrical device 1000 may include another input device 1020 (or corresponding interface circuitry, as discussed above). Examples of the other input device 1020 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1000 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1000 may be any other electronic device that processes data. In some embodiments, the electrical device 1000 may comprise multiple discrete physical components. Given the range of devices that the electrical device 1000 can be manifested as in various embodiments, in some embodiments, the electrical device 1000 can be referred to as a computing device or a computing system.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 is an integrated circuit package substrate comprising: a core layer; a plurality of build-up layers on the core layer, each build-up layer comprising a dielectric and metal; and a cavity, wherein a first portion of the cavity is defined in a first build-up layer, a second portion of the cavity is defined in a second build-up layer, and a third portion of the cavity connects the first portion with the second portion through at least one layer other than first build-up layer and the second build-up layer.

Example 2 includes the subject matter of Example 1, wherein the third portion is defined in a plurality of build-up layers other than the first build-up layer and the second build-up layer.

Example 3 includes the subject matter of Example 1 or 2, wherein the first build-up layer is on a first side of the core layer, the second build-up layer is on a second side of the core layer, and the third portion of the cavity connecting the first portion and the second portion is defined at least in part in the core layer.

Example 4 includes the subject matter of Example 3, wherein the third portion is defined in the core layer and a third build-up layer.

Example 5 includes the subject matter of any one of Examples 1-4, wherein the first cavity is defined at least in part by metal within the first build-up layer and the second cavity is defined at least in part by metal within the second build-up layer.

Example 6 includes the subject matter of any one of Examples 1-5, wherein the first portion of the cavity is a first microchannel, the second portion of the cavity is a second microchannel, and the third portion of the cavity is a duct connecting the first microchannel and the second microchannel.

Example 7 includes the subject matter of Example 6, wherein the first portion of the cavity is defined by a first cross-section in the first build-up layer, the second portion of the cavity is defined by a second cross-section in the second build-up layer, and the third portion of the cavity is defined by a third cross-section between the first build-up layer and the second build-up layer.

Example 8 includes the subject matter of Example 6 or 7, wherein the cavity comprises a fourth portion that connects the first portion of the cavity with the second portion of the cavity.

Example 9 includes the subject matter of Example 6 or 7 or 8, wherein the first microchannel defines a first sealed heat pipe structure and the second microchannel defines a second sealed heat pipe structure.

Example 10 includes the subject matter of any one of Examples 1-5, wherein the first portion, second portion, and third portion of the cavity together define a microchannel.

Example 11 includes the subject matter of Example 10, wherein the first portion of the cavity is defined by a first cross-section in the first build-up layer, the second portion of the cavity is defined by a second cross-section in the second build-up layer, and the third portion of the cavity is defined by a third cross-section between the first build-up layer and the second build-up layer.

Example 12 includes the subject matter of Example 10 or 11, wherein the microchannel defines a sealed heat pipe structure.

Example 13 includes the subject matter of any one of Examples 1-12, wherein the core layer comprises a glass material.

Example 14 includes the subject matter of any one of Examples 1-13, wherein the first build-up layer comprises a glass material and the second build-up layer comprises a glass material.

Example 15 includes the subject matter of any one of Examples 1-14, further comprising a hydrophilic material on a wall of the cavity.

Example 16 is an integrated circuit package comprising the integrated circuit package substrate of any one of Examples 1-15 and an integrated circuit die coupled to the package substrate.

Example 17 is a computing system comprising a main circuit board and the integrated circuit package of Example 16 coupled to the main circuit board.

Example 18 is a method of forming an integrated circuit package substrate, comprising: forming a first layer of the package substrate, the first layer defining a vertical channel; forming a second layer of the package substrate on a first side of the first layer, the second layer defining a first microchannel connected to the vertical channel in the first layer; and forming a third layer of the package substrate on a second side of the first layer opposite the first side, the third layer defining a second microchannel connected to the vertical channel in the first layer.

Example 19 includes the subject matter of Example 18, further comprising depositing a hydrophilic material on a wall of the vertical channel, the first microchannel, or the second microchannel.

Example 20 includes the subject matter of Example 18 or 19, further comprising depositing a thermally decomposable material (TDM) in the vertical channel before forming the second layer and the third layer.

Example 21 includes the subject matter of any one of Examples 18-20, wherein the first layer comprises a first sub-layer and a second sub-layer, and forming the first layer comprises bonding the first sub-layer and the second sub-layer together.

Example 22 is a method of forming an integrated circuit package substrate, comprising: forming a first layer of the package substrate, the first layer defining a vertical channel; forming a second layer of the package substrate, the second layer defining a first microchannel; forming a third layer of the package substrate, the third layer defining a second microchannel; and attaching the second layer to the first layer and the third layer to the first layer such that the first microchannel is connected to the vertical channel and the second microchannel is connected to the vertical channel.

Example 23 includes the subject matter of Example 22, further comprising depositing a hydrophilic material on a wall of the vertical channel, the first microchannel, or the second microchannel.

In the above description, various aspects of the illustrative implementations have been described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials, and configurations have been set forth to provide a thorough understanding of the illustrative implementations. However, it will be apparent to one skilled in the art that the present disclosure may be practiced without all of the specific details. In other instances, well-known features have been omitted or simplified in order not to obscure the illustrative implementations.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

The above description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature. Further, as used herein, the phrase “located on” in the context of a first layer or component located on a second layer or component may refer to the first layer or component being directly physically attached to the second part or component (no layers or components between the first and second layers or components) or physically attached to the second layer or component with one or more intervening layers or components. Additionally, as used herein, the term “adjacent” may refer to layers or components that are in physical contact with each other. That is, there is no layer or component between the stated adjacent layers or components. For example, a layer X that is adjacent to a layer Y refers to a layer that is in physical contact with layer Y.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

1. An integrated circuit package substrate comprising:
a core layer;
a plurality of build-up layers on the core layer, each build-up layer comprising a dielectric and metal; and
a cavity, wherein a first portion of the cavity is defined in a first build-up layer, a second portion of the cavity is defined in a second build-up layer, and a third portion of the cavity connects the first portion with the second portion through at least one layer other than first build-up layer and the second build-up layer.

2. The integrated circuit package substrate of claim 1, wherein the third portion is defined in a plurality of build-up layers other than the first build-up layer and the second build-up layer.

3. The integrated circuit package substrate of claim 1, wherein the first build-up layer is on a first side of the core layer, the second build-up layer is on a second side of the core layer, and the third portion of the cavity connecting the first portion and the second portion is defined at least in part in the core layer.

4. The integrated circuit package substrate of claim 3, wherein the third portion is defined in the core layer and a third build-up layer.

5. The integrated circuit package substrate of claim 1, wherein the first cavity is defined at least in part by metal within the first build-up layer and the second cavity is defined at least in part by metal within the second build-up layer.

6. The integrated circuit package substrate of claim 1, wherein the first portion of the cavity is a first microchannel, the second portion of the cavity is a second microchannel, and the third portion of the cavity is a duct connecting the first microchannel and the second microchannel.

7. The integrated circuit package substrate of claim 6, wherein the first portion of the cavity is defined by a first cross-section in the first build-up layer, the second portion of the cavity is defined by a second cross-section in the second build-up layer, and the third portion of the cavity is defined by a third cross-section between the first build-up layer and the second build-up layer.

8. The integrated circuit package substrate of claim 6, wherein the cavity comprises a fourth portion that connects the first portion of the cavity with the second portion of the cavity.

9. The integrated circuit package substrate of claim 6, wherein the first microchannel defines a first sealed heat pipe structure and the second microchannel defines a second sealed heat pipe structure.

10. The integrated circuit package substrate of claim 1, wherein the first portion, second portion, and third portion of the cavity together define a microchannel.

11. The integrated circuit package substrate of claim 10, wherein the first portion of the cavity is defined by a first cross-section in the first build-up layer, the second portion of the cavity is defined by a second cross-section in the second build-up layer, and the third portion of the cavity is defined by a third cross-section between the first build-up layer and the second build-up layer.

12. The integrated circuit package substrate of claim 10, wherein the microchannel defines a sealed heat pipe structure.

13. The integrated circuit package substrate of claim 1, wherein the core layer comprises a glass material.

14. The integrated circuit package substrate of claim 1, wherein the first build-up layer comprises a glass material and the second build-up layer comprises a glass material.

15. The integrated circuit package substrate of claim 1, further comprising a hydrophilic material on a wall of the cavity.

16. A method of forming an integrated circuit package substrate, comprising:
forming a first layer of the package substrate, the first layer defining a vertical channel;
forming a second layer of the package substrate on a first side of the first layer, the second layer defining a first microchannel connected to the vertical channel in the first layer; and
forming a third layer of the package substrate on a second side of the first layer opposite the first side, the third layer defining a second microchannel connected to the vertical channel in the first layer.

17. The method of claim 16, further comprising depositing a hydrophilic material on a wall of the vertical channel, the first microchannel, or the second microchannel.

18. The method of claim 16, wherein the first layer comprises a first sub-layer and a second sub-layer, and forming the first layer comprises bonding the first sub-layer and the second sub-layer together.

19. A method of forming an integrated circuit package substrate, comprising:
forming a first layer of the package substrate, the first layer defining a vertical channel;
forming a second layer of the package substrate, the second layer defining a first microchannel;
forming a third layer of the package substrate, the third layer defining a second microchannel; and
attaching the second layer to the first layer and the third layer to the first layer such that the first microchannel is connected to the vertical channel and the second microchannel is connected to the vertical channel.

20. The method of claim 19, further comprising depositing a hydrophilic material on a wall of the vertical channel, the first microchannel, or the second microchannel.
